(19) United States
(12) Patent Application Publication
(10) Pub. No.: US 2026/0090448 A1
(43) Pub. Date: Mar. 26, 2026

(54) SEMICONDUCTOR DEVICE AND SEMICONDUCTOR APPARATUS

(71) Applicant: Fujian Jinhua Integrated Circuit Co., Ltd., Fujian (CN)

(72) Inventor: Xiaobing CHEN, Fujian (CN)

(73) Assignee: Fujian Jinhua Integrated Circuit Co., Ltd., Fujian (CN)

(21) Appl. No.: 19/023,359

(22) Filed: Jan. 16, 2025

(30) Foreign Application Priority Data
Sep. 20, 2024 (CN) 202411317001.9

(51) Int. Cl. H01L 23/31; H01L 23/29; H10B 12/00

(52) U.S. Cl. CPC H10W 74/111; H10B 12/31; H10W 74/43

(57) ABSTRACT

The present application provides a semiconductor device and a semiconductor apparatus. The semiconductor device includes a substrate, a capacitor structure, a semiconductor conductive layer, a cover layer, and multiple voids; where the capacitor structure is disposed on the substrate; the capacitor structure includes multiple capacitors; the semiconductor conductive layer includes a first portion and a second portion, the first portion covers the capacitor structure and directly contacts the capacitor structure; the second portion is filled between adjacent capacitors; the cover layer is located on the first portion and is in direct contact with the first portion; a surface of the cover layer facing the semiconductor conductive layer has an undulating surface profile, and the surface profile has peaks and valleys, the first portion being extended into the valleys; at least one void is located within the first portion in the valley.

### CROSS-REFERENCE TO RELATED APPLICATION

This application claims priority to Chinese Patent Application No. 202411317001.9, filed on Sep. 20, 2024 and entitled “SEMICONDUCTOR STORAGE DEVICE AND SEMICONDUCTOR STORAGE APPARATUS”, which is hereby incorporated by reference in its entirety.

### BACKGROUND

### Technical Field

The present application relates to the field of semiconductor technology and, in particular, to a semiconductor device and a semiconductor apparatus.

### Description of Related Art

With the continuous development of semiconductor technology, the semiconductor device such as a dynamic random access memory (Dynamic Random Access Memory, DRAM for short) or a static random access memory (Static Random Access Memory, SRAM for short) is of increasingly widespread application and has been widely used in fields such as computers and communications.

In related technologies, stacked film layers of a semiconductor device are prone to delamination or fracture, which reduces the performance of the semiconductor device.

### SUMMARY

In view of the above problem, the present application provides a semiconductor device and a semiconductor apparatus, which can reduce or even avoid delamination between a semiconductor conductive layer and a cover layer, thereby improving the performance of the semiconductor device.

In order to achieve the above objectives, embodiments of the present application provide the following technical solutions.

In a first aspect of the embodiments of the present application, a semiconductor device is provided, which includes:
a substrate;
a capacitor structure disposed on the substrate; where the capacitor structure includes multiple capacitors;
a semiconductor conductive layer including a first portion and a second portion, where the first portion covers the capacitor structure and directly contacts the capacitor structure; and the second portion is filled between adjacent capacitors;
a cover layer located on the first portion and in direct contact with the first portion; where a surface of the cover layer facing the semiconductor conductive layer has an undulating surface profile, and the surface profile has peaks and valleys, the first portion being extended into the valleys; and
multiple voids, where at least one void is located within the first portion in the valley.

In one possible implementation, a bottom of the at least one void facing the substrate is located between an adjacent peak and a surface of the cover layer away from the substrate.

In one possible implementation, there is a minimum distance D1 between the at least one void and a top surface of the capacitor structure away from the substrate;
there is a distance D2 between adjacent capacitors in the capacitor structure; and D1 is greater than D2.

In one possible implementation, the multiple voids are disposed within the first portion at intervals.

In one possible implementation, the multiple voids include a first void, a second void and a third void, the third void being located within the first portion in the valley;
in a first direction, the first void is located at one side of the third void, and the second void is located at the other side of the third void;
there is a first spacing D3 between the first void and the third void, and there is a second spacing D4 between the second void and the third void; where the first spacing D3 is less than or equal to the second spacing D4.

In one possible implementation, widths of the void gradually decrease along a direction of the cover layer pointing towards the semiconductor conductive layer.

In one possible implementation, when a section perpendicular to the substrate is taken as a longitudinal section, the void has a longitudinal section shape which is conical or trapezoidal.

In one possible implementation, when a section perpendicular to the substrate is taken as a longitudinal section, the void has a longitudinal section shape which is semi-circular or arc-shaped.

In one possible implementation, the semiconductor conductive layer is made of a material including silicon germanium.

In one possible implementation, the cover layer is made of an insulating material; the insulating material is selected from at least one of: high-density plasma (HDP) oxide, tetraethyl orthosilicate (TEOS), undoped silica glass (USG), phosphosilicate glass (PSG), borosilicate glass (BSG), borophosphosilicate glass (BPSG), fluorinated silicate glass (FSG), spin-on glass (SOG), tetraorthosilicate zirconium (TOSZ), silicon nitride or silicon nitride oxide.

In one possible implementation, the cover layer is made of a conductive material; the conductive material is selected from at least one of: tungsten, titanium nitride, or tungsten nitride.

In one possible implementation, the capacitor includes a first electrode plate, a second electrode plate, and a capacitor dielectric layer located between the first electrode plate and the second electrode plate;
the semiconductor conductive layer is disposed on the second electrode plate.

In a second aspect of the embodiments of the present application, a semiconductor apparatus is provided, which includes: a package and the semiconductor device as described in the first aspect; the package encapsulates the semiconductor device.

In the semiconductor device and the semiconductor apparatus according to the embodiments of the present application, there are multiple voids between a semiconductor conductive layer and a cover layer, and the multiple voids can block the transmission of stress generated during a contraction or expansion process of the semiconductor conductive layer and/or the cover layer, avoiding stress concentration at an interface between the semiconductor conductive layer and the cover layer, thereby avoiding delamination between the semiconductor conductive layer and the cover layer, and improving the performance of the semiconductor device.

A surface of the cover layer facing the semiconductor conductive layer has an undulating surface profile, and the surface profile has peaks and valleys. A first portion extends into the valleys, allowing the first portion to fit into the cover layer so that the strength of bonding between the cover layer and the semiconductor conductive layer can be improved. In addition, a part of the first portion extending into the valley forms a sharp part, where the stress is highest, thus at least one void is located within the first portion in the valley, which can avoid stress concentration at the interface between the semiconductor conductive layer and the cover layer as much as possible.

In addition to the technical problems solved by the embodiments of the present application, the technical features constituting the technical solution and the beneficial effects brought by these technical features, other technical problems that can be solved by the semiconductor device and the semiconductor apparatus according to the embodiments of the present application, other technical features included in the technical solution and the beneficial effects brought by these technical features will be further explained in detail in the Description of Embodiments.

### BRIEF DESCRIPTION OF THE DRAWINGS

In order to more clearly describe the technical solution in embodiments of the present application or the prior art, in the following, the drawings that need to be used in the description of the embodiments or the prior art will be briefly introduced. Apparently, the drawings in the following description are a part of embodiments of the present application. For persons of ordinary skill in the art, other drawings can be obtained based on these drawings without creative efforts.

FIG. 1 is a structural schematic diagram of a semiconductor device provided in an embodiment of the present application.

FIG. 2 is a schematic diagram of forming a capacitive contact structure during a preparation process of a semiconductor device provided in an embodiment of the present application.

FIG. 3 is a schematic diagram of forming a support structure during a preparation process of a semiconductor device provided in an embodiment of the present application.

FIG. 4 is a schematic diagram of forming a capacitor hole during a preparation process of a semiconductor device provided in an embodiment of the present application.

FIG. 5 is a schematic diagram of forming a first electrode plate during a preparation process of a semiconductor device provided in an embodiment of the present application.

FIG. 6 is a schematic diagram of forming a photoresist layer during a preparation process of a semiconductor device provided in an embodiment of the present application.

FIG. 7 is a schematic diagram of removing part of a support structure during a preparation process of a semiconductor device provided in an embodiment of the present application.

FIG. 8 is a schematic diagram of forming a capacitor dielectric layer during a preparation process of a semiconductor device provided in an embodiment of the present application.

FIG. 9 is a schematic diagram I of forming a second electrode plate during a preparation process of a semiconductor device provided in an embodiment of the present application.

FIG. 10 is a schematic diagram II of forming a second electrode plate during a preparation process of a semiconductor device provided in an embodiment of the present application.

FIG. 11 is a schematic diagram I of forming a semiconductor conductive layer during a preparation process of a semiconductor device provided in an embodiment of the present application.

FIG. 12 is a schematic diagram II of forming a semiconductor conductive layer during a preparation process of a semiconductor device provided in an embodiment of the present application.

FIG. 13 is a schematic diagram I of forming a cover layer during a preparation process of a semiconductor device provided in an embodiment of the present application.

FIG. 14 is a schematic diagram II of forming a cover layer during a preparation process of a semiconductor device provided in an embodiment of the present application.

FIG. 15 is a schematic diagram I of forming a conductive plug during a preparation method of a semiconductor device provided in an embodiment of the present application.

FIG. 16 is a schematic diagram II of forming a conductive plug during a preparation method of a semiconductor device provided in an embodiment of the present application.

### DESCRIPTION OF THE EMBODIMENTS

As described in the background section, stacked film layers of a semiconductor device in related technologies are prone to delamination or fracture. The inventor has researched and found that the reason for this problem lies in: during the use of the semiconductor device, film layers undergo thermal expansion and contraction, and thermal expansion coefficients of the stacked film layers are different, resulting in different degrees of deformation of the stacked film layers, which in turn leads to delamination or fracture of the stacked film layers, thereby reducing the performance of the semiconductor device.

Regarding the above technical problem, embodiments of the present application provide a semiconductor device and a semiconductor apparatus, where there are multiple voids between a semiconductor conductive layer and a cover layer, and the multiple voids can block the transmission of stress generated during a contraction or expansion process of the semiconductor conductive layer and/or the cover layer, avoiding stress concentration at an interface between the semiconductor conductive layer and the cover layer, thereby avoiding delamination between the semiconductor conductive layer and the cover layer, and improving the performance of the semiconductor device.

A surface of the cover layer facing the semiconductor conductive layer has an undulating surface profile, and the surface profile has peaks and valleys. A first portion extends into the valleys, allowing the first portion to fit into the cover layer so that the strength of bonding between the cover layer and the semiconductor conductive layer can be improved. In addition, a part of the first portion extending into the valley forms a sharp part, where the stress is highest, thus at least one void is located within the first portion in the valley, which can avoid stress concentration at the interface between the semiconductor conductive layer and the cover layer as much as possible.

In order to make the above objectives, features, and advantages of embodiments of the present application more obvious and understandable, the technical solutions in the embodiments of the present application will be clearly and comprehensively described below in conjunction with the accompanying drawings. Apparently, the described embodiments are only a part of the embodiments of the present application rather than all embodiments. Based on the embodiments in the present application, all other embodiments obtained by the persons of ordinary skill in the art without creative efforts are within the scope of protection of the present application.

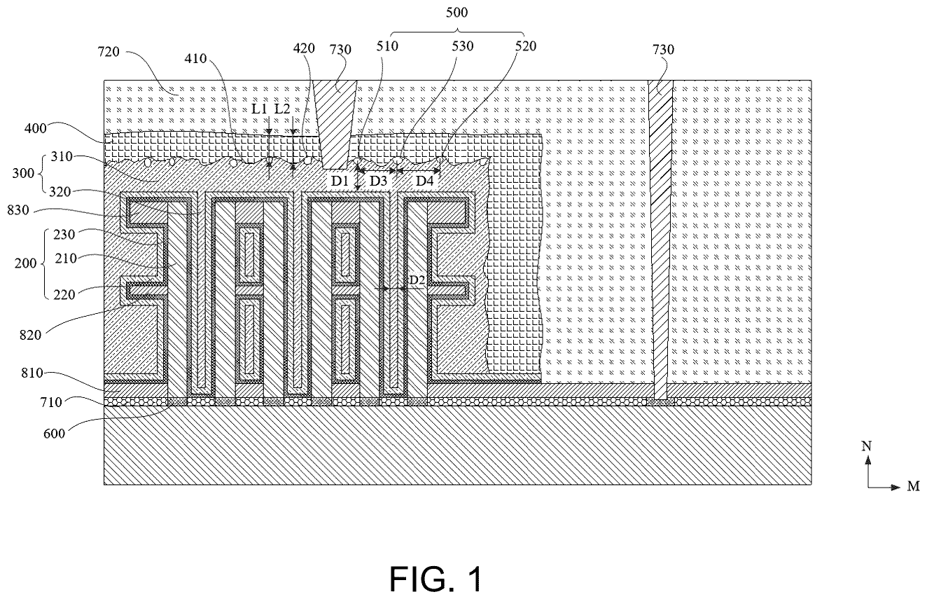

With reference to FIG. 1, an embodiment of the present application provides a semiconductor device. The semiconductor device may be a dynamic random access memory or a static random access memory.

The semiconductor device includes a substrate 100, which serves as a main carrier component of the semiconductor structure for carrying components disposed thereon. The substrate 100 may be any substrate 100 suitable for manufacturing a semiconductor element, such as a silicon (Si) substrate, an epitaxial silicon (epi-Si) substrate, a silicon germanium (SiGe) substrate, a silicon carbide (SiC) substrate, or a silicon-on-insulator (silicon-on-insulator, SOI) substrate, but not limited to thereto.

The semiconductor device further includes a capacitor structure disposed on the substrate 100. The capacitor structure includes multiple capacitors 200, which are disposed on the substrate 100 at intervals. Among them, the capacitor 200 serves as a storage device for the semiconductor device, used for charge storage to achieve data storage and reading functions.

Each capacitor 200 includes a first electrode plate 210, a second electrode plate 220, and a capacitor dielectric layer 230. The capacitor dielectric layer 230 is disposed between the first electrode plate 210 and the second electrode plate 220 to achieve insulation between them. Among them, one of the first electrode plate 210 and the second electrode plate 220 serves as a lower electrode of the capacitor, and the other of the first electrode plate 210 and the second electrode plate 220 serves as an upper electrode of the capacitor. The following embodiments are described using an example where the first electrode plate 210 is taken as the lower electrode and the second electrode plate 220 is taken as the upper electrode.

With continued reference to FIG. 1, the second electrode plates 220 are connected together to form a whole, and are connected to a conductive plug 730 through the semiconductor conductive layer 300 and the cover layer 400 to achieve electrical connection between a peripheral circuit and the capacitors 200. And the first electrode plates 210 of the multiple capacitors 200 are independent from each other, and each first electrode plate 210 may be electrically connected to a source region or a drain region of the substrate 100 through a capacitive contact structure 600.

In this embodiment, reference is made to FIG. 1. The first electrode plate 210 is a columnar body perpendicular to the substrate 100. In this way, the volume of the first electrode plate 210 can be increased, thereby improving the strength of the first electrode plate 210 and preventing the collapse of the capacitor 200, thereby improving the yield of the semiconductor structure.

The first electrode plate 210 and the second electrode plate 220 may be made of a material including a conductive material (such as tungsten metal and titanium nitride). The capacitor dielectric layer 230 may be made of a dielectric material with a high dielectric constant, for example, the dielectric material may include at least one of: ZrOₓ, HfOₓ, ZrTiOₓ, RuOₓ, SbOₓ, AlOₓ. That is to say, the capacitor dielectric layer 230 may be made of a material selected from any one or more of the above materials. In an implementation, the capacitor dielectric layer 230 may be a lamination structure, for example, the capacitor dielectric layer 230 may include a three-layer structure, and the three-layer structure may be made of zirconia-alumina-zirconia.

The semiconductor device further includes a semiconductor conductive layer 300 and a cover layer 400. The semiconductor conductive layer 300 includes a first portion 310 and a second portion 320. The first portion 310 covers the capacitor structure and directly contacts the capacitor structure; the second portion 320 is filled between adjacent capacitors 200. Alternatively, the semiconductor conductive layer 300 is disposed on the second electrode plate 220 and is in contact with and electrically connected to the second electrode plate 220 of the capacitor 200.

The cover layer 400 is disposed on the first portion 310 and is in direct contact with the first portion 310. A surface of the cover layer 400 facing the semiconductor conductive layer 300 has an undulating surface profile, and the surface profile has peaks 410 and valleys 420, the first portion 310 being extended into the valleys 420. Alternatively, the first portion 310 also has a protruding region which can be embedded in the valley 420 to improve the fitness between the semiconductor conductive layer 300 and the cover layer 400.

In this embodiment, the semiconductor conductive layer 300 may be made of a material including germanium silicon or polycrystalline silicon, and the cover layer 400 may be made of an insulating material or a conductive material. In one example, the cover layer 400 is made of an insulating material, and the insulating material is selected from at least one of: HDP oxide, TEOS, USG, PSG, BSG, BPSG, FSG, SOG, TOSZ, silicon nitride, and silicon nitride oxide. Among them, TEOS is an abbreviation for tetraethyl orthosilicate; USG is an abbreviation for undoped silica glass; PSG is an abbreviation for phosphosilicate glass; BSG is an abbreviation for borosilicate glass; BPSG is an abbreviation for borophosphosilicate glass; FSG is an abbreviation for fluorinated silicate glass; SOG is an abbreviation for spin-on glass; TOSZ is an abbreviation for tetraorthosilicate zirconium.

In another example, the cover layer 400 is made of a conductive material; where the conductive material is selected from at least one of: tungsten, titanium nitride, or tungsten nitride.

The capacitor structure is connected to the conductive plug 730 through the semiconductor conductive layer 300, or the capacitor structure is connected to the conductive plug 730 through the semiconductor conductive layer 300 and the cover layer 400, in order to facilitate the electrical connection between the capacitor structure and the peripheral circuit, thereby achieving data storage or reading.

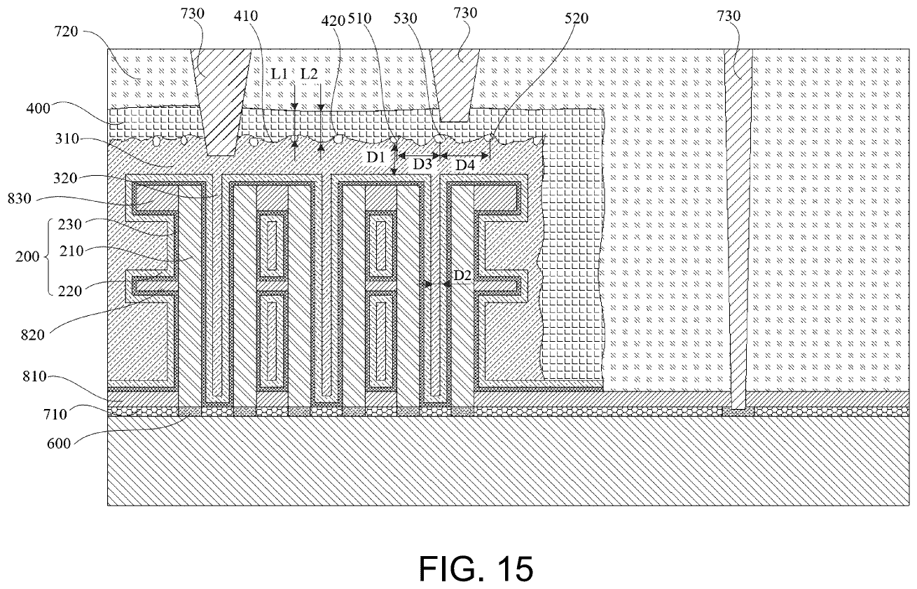

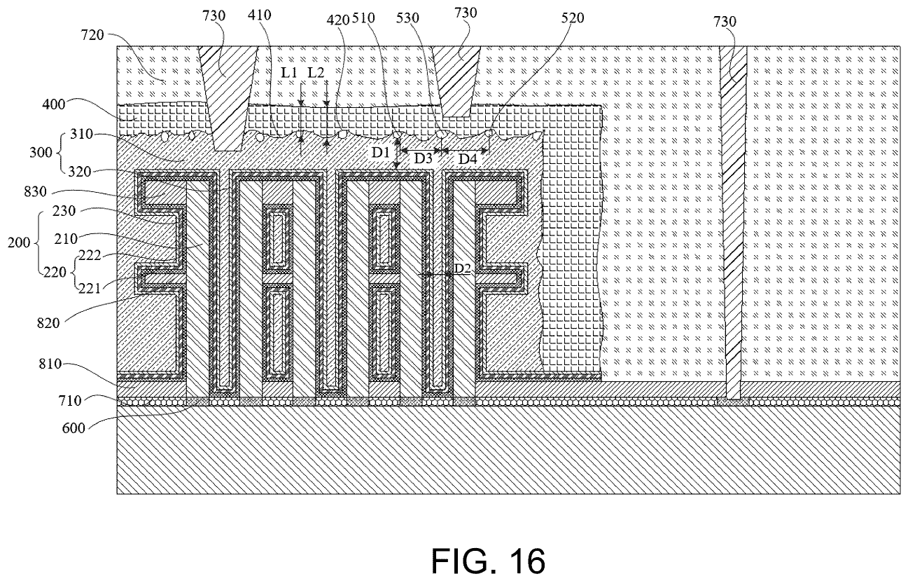

It should be understood that, with reference to FIG. 1, when the cover layer 400 is made of an insulating material, the capacitor structure is connected to the conductive plug 730 through the semiconductor conductive layer 300. And referring to FIG. 15 and FIG. 16, when the cover layer 400 is made of a conductive material, the capacitor structure is connected to the conductive plug 730 through the semiconductor conductive layer 300 and/or the cover layer 400.

The thermal expansion coefficient varies significantly between the semiconductor conductive layer 300 and the cover layer 400, rendering that the semiconductor device is prone to delamination or fracture during operation. Therefore, the semiconductor device provided in this embodiment further includes multiple voids 500, at least one void 500 is located within the first portion 310 in the valley 420. Alternatively, multiple voids 500 are disposed within the first portion 310 at intervals, and at least one void 500 is provided within the first portion 310 in the valley 420. Any adjacent voids 500 may have an equal distance therebetween or have an unequal distance therebetween, and the specific layout can be based on the actual situation.

In this way, the use of multiple voids 500 may block the transmission of stress generated during the contraction or expansion process of the semiconductor conductive layer 300 and/or the cover layer 400, avoiding stress concentration at the interface between the semiconductor conductive layer 300 and the cover layer 400, thereby avoiding delamination between the semiconductor conductive layer 300 and the cover layer 400, and improving the performance of the semiconductor device.

The surface of the cover layer 400 facing the semiconductor conductive layer 300 has an undulating surface profile, and the surface profile has peaks 410 and valleys 420. The first portion 310 extends into the valleys 420, allowing the first portion 310 to fit into the cover layer 400 so that the strength of bonding between the cover layer 400 and the semiconductor conductive layer 300 can be improved. In addition, part of the first portion 310 extending into the valley 420 forms a sharp part, where the stress is highest, thus at least one void 500 is located within the first portion 310 in the valley 420, which can avoid stress concentration at the interface between the semiconductor conductive layer 300 and the cover layer 400 as much as possible.

It should be noted that in this embodiment, one, two or even more voids 500 are located within the first portion 310 in the valley 420. The specific layout needs to be based on the size of the first portion 310 located in the valley 420. In addition, except for the at least one void 500 located within the first portion 310 in the valley 420, the remaining voids 500 may be disposed between the semiconductor conductive layer 300 and the cover layer 400.

On the premise of having the function of blocking stress transmission, multiple voids 500 may further be used as thermal insulation components, utilizing much lower thermal conductivity of air compared to solid materials. These voids 500 may significantly reduce the heat conduction from the cover layer 400 to the semiconductor conductive layer 300, thereby improving the thermal stability of the entire capacitor structure and enhancing the thermal stability of the semiconductor device.

In one possible implementation, a bottom of at least one void 500 facing the substrate 100 is located between an adjacent peak 410 and a surface of the cover layer 400 away from the substrate 100. In other words, a distance between the bottom of the at least one void 500 facing the substrate 100 and the surface of the cover layer 400 away from the substrate 100 is a first distance L1, and a distance between any adjacent peak 410 and the surface of the cover layer 400 away from the substrate 100 is a second distance L2, where the first distance L1 is smaller than the second distance L2. In this way, while ensuring that at least one void 500 effectively reduces local stress concentration, it is also possible to avoid the size of the at least one void 500 being too large perpendicular to the cover layer 400, reducing the impact of the at least one void 500 on the conductivity of the semiconductor conductive layer 300, thereby ensuring the performance of the semiconductor device.

It should be understood that the size relationship between the first distance L1 and the second distance L2 is not simply limited to the above description. The first distance L1 may also be equal to the second distance L2, specifically, it can be changed according to the performance requirements of the semiconductor device or the control of process parameters.

With continued reference to FIG. 1, a filling region is enclosed by the second electrode plate 220 in the capacitor dielectric layer 230. In this way, the semiconductor conductive layer 300 may not only cover the second electrode plate 220, but also fill the filling region, increasing a contact area between the semiconductor conductive layer 300 and the second electrode plate 220, thereby reducing the contact resistance between the semiconductor conductive layer 300 and the second electrode plate 220.

There is a minimum distance D1 between the at least one void 500 and a top surface of the capacitor structure away from the substrate 100; that is, there is a minimum distance D1 between the at least one void 500 and a top surface of the second electrode plate 220 away from the substrate 100.

There is a distance D2 between adjacent capacitors 200 in the capacitor structure; That is, a width of the filling region enclosed by the second electrode plate 220 between adjacent first electrode plates 210 constitutes D2. It should be noted that the width in this embodiment is a dimension in the first direction M in FIG. 1

In this embodiment, the distance D1 is greater than the distance D2, which ensures that the thickness of the semiconductor conductive layer 300 located on the top surface of the capacitor structure away from the substrate 100 is greater than the thickness of the semiconductor conductive layer 300 located in the filling region. This setting can increase the thickness of the first portion 310, thereby providing a better heat dissipation path and helping to reduce the heat generated during the operation of the capacitor structure, thereby improving the stability and durability of the entire capacitor structure.

In order to facilitate a detailed description of the relative relationship between at least one void 500 located within the first portion 310 in the valley 420 and an adjacent void 500 thereof, taking the number of voids 500 located within the first portion 310 in the valley 420 being one as an example.

Exemplarily, multiple voids 500 include a first void 510, a second void 520 and a third void 530, the third void 530 being located within the first portion 310 in the valley 420. In the first direction M, the first void 510 is located at one side of the third void 530, and the second void 520 is located at the other side of the third void 530. That is, the first void 510 and the second void 520 are located at either sides of the third void 530 and disposed at intervals.

There is a first spacing D3 between the first void 510 and the third void 530, and there is a second spacing D4 between the second void 520 and the third void 530. The first spacing D3 is less than or equal to the second spacing D4.

In this embodiment, the flow path of current in the semiconductor conductive layer 300 can be affected through reasonable arrangement of the first void 510, the second void 520 and the third void 530. With the first spacing D3 being less than or equal to the second spacing D4, the current in the semiconductor conductive layer 300 tends to flow through a narrower channel between the first void 510 and the second void 520, which helps to achieve uniform distribution or directional guidance of current and improve the conductivity efficiency and stability of the semiconductor device.

In addition, the semiconductor device may generate heat during operation, leading to thermal expansion. Since the cover layer 400 and the semiconductor conductive layer 300 have different thermal expansion coefficients, thermal stress will be generated between them. By properly arranging the voids 500, especially placing the third void 530 in the valley 420, stress concentration caused by thermal expansion differences can be reduced. Meanwhile, a layout where the first spacing D3 is less than or equal to the second spacing D4 helps to disperse these stresses and avoid material failure resulting from excessive local stress.

In one possible implementation, widths of the void 500 gradually decrease along a direction of the cover layer 400 pointing towards the semiconductor conductive layer 300. The direction of the cover layer 400 pointing towards the semiconductor conductive layer 300 is the second direction N shown in FIG. 1. A width of the void 500 may be a dimension of the void 500 in the first direction M.

The cover layer 400 and the semiconductor conductive layer 300 are made of different materials, and thermal expansion differences will occur when the temperature changes. The generated thermal stress is mainly concentrated at the interface between the cover layer 400 and the semiconductor conductive layer 300. Therefore, the width of the void 500 near the interface is the largest, which helps to provide a better stress buffer zone, better alleviate the stress at the interface between the cover layer 400 and the semiconductor conductive layer 300, and thus better avoid delamination between the cover layer 400 and the semiconductor conductive layer 300, thereby improving the performance of the semiconductor device.

In addition, along the second direction N and towards the substrate 100, widths of the void 500 gradually decrease. This structure enables the semiconductor device to more effectively disperse and absorb stress without sacrificing overall strength when facing external factors (such as temperature changes and mechanical vibrations), thus avoiding damage caused by excessive local stress.

It should be understood that there are multiple options for the shape of a void 500. In one example, when a section perpendicular to the substrate 100 is taken as a longitudinal section, the void 500 has a longitudinal section shape which is conical or trapezoidal. In this way, a wider void portion can absorb more stress changes, while a narrower portion further limits stress transmission, effectively reducing stress concentration at the interface between the cover layer 400 and the semiconductor conductive layer 300. In another example, when a section perpendicular to the substrate 100 is taken as a longitudinal section, the void 500 has a longitudinal section shape which is semi-circular or arc-shaped. The semi-circular or arc-shaped void shape provides smooth transition edges in the longitudinal section, which helps to reduce sudden changes in stress at the interface and guide stress propagation along a smoother path, reducing the possibility of stress concentration.

The longitudinal section shape of the void 500, in spite of it being conical, trapezoidal, semi-circular, or arc-shaped, has a commonality in that the stress caused by the thermal expansion differences between the cover layer 400 and the semiconductor conductive layer 300 can be delicately guided and dispersed by changing the width or shape of the void 500, thereby reducing the stress concentration at the interface. When the stress is effectively dispersed, the risk of delamination between the cover layer 400 and the semiconductor conductive layer 300 will be greatly reduced. Therefore, on the premise of reducing the risk of delamination, the selectivity of the longitudinal section shape of the void 500 can be increased.

The semiconductor device provided in the embodiments of the present application may further include a transistor, a word line structure, and a bit line structure. Exemplarily, in this embodiment, the substrate 100 already includes a semiconductor device, for example, a transistor (not shown in the figure) and a word line structure (not shown in the figure) are disposed in the substrate 100, where the word line structure is connected to a gate of the transistor to control turning-on or turning-off of the transistor. The transistor further includes a source and a drain. One of the source and the drain is connected to a capacitor structure, while the other is used to connect to a bit line structure. The voltage signal on the word line structure can control turning-on or turning-off of the transistor, and then through the bit line structure, data information stored in the capacitor structure may be read, or through the bit line structure, data information can be written into the capacitor structure for storage.

It should be noted that in this embodiment, the capacitor structure may be connected to one of the source and the drain through the capacitive contact structure 600. In order to facilitate further detailed description of the structure of the semiconductor device, the following will provide auxiliary explanations by describing the preparation method of the semiconductor device.

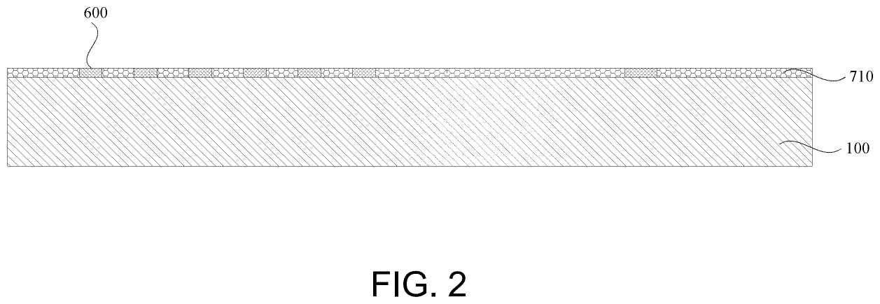

Exemplarily, a capacitive contact structure 600 is formed on a substrate 100, and the capacitive contact structure 600 is connected to one of the source and the drain. For example, referring to FIG. 2, a dielectric layer 710 may be formed on the substrate 100 through a deposition process; the dielectric layer 710 is then patterned to form a contact hole within the dielectric layer 710, the contact hole is used to expose at least a part of the source or at least a part of the drain; and then a conductive material is deposited in the contact hole by using a deposition process, to form a capacitive contact structure 600. A top surface of the capacitive contact structure 600 is flush with a top surface of the dielectric layer 710.

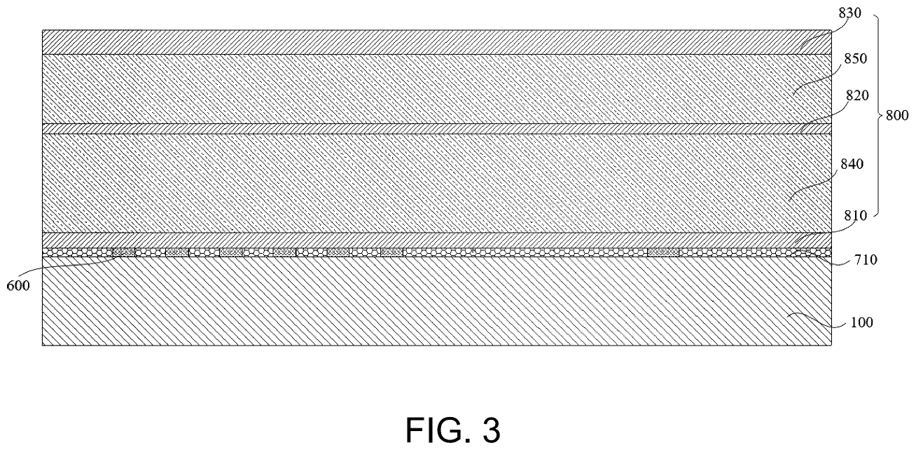

With reference to FIG. 3, a support structure 800 is formed on the dielectric layer 710, where the support structure 800 is a stacked structure. Exemplarily, the support structure 800 includes a first support layer 810, a first sacrificial layer 840, a second support layer 820, a second sacrificial layer 850 and a third support layer 830 stacked in sequence, where the first support layer 810 is disposed on the substrate 100.

The first support layer 810, the second support layer 820, and the third support layer 830 may be made of an insulating material (including silicon nitride or the like), and the first sacrificial layer 840 and the second sacrificial layer 850 may be made of an insulating material (including silicon oxide or the like).

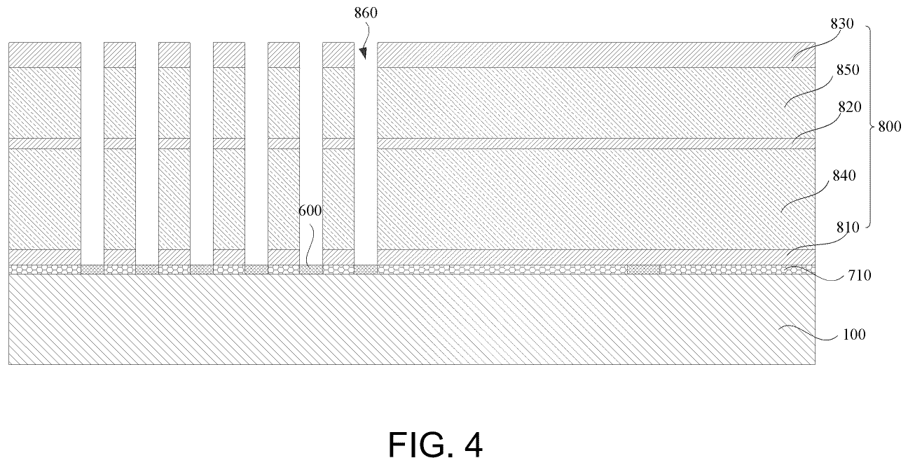

With reference to FIG. 4, the support structure 800 is patterned, and a capacitor hole 860 is formed inside the support structure 800, where the capacitor hole 860 penetrates the support structure 800 in a direction perpendicular to the substrate 100, so that the capacitive contact structure 600 may be exposed though the capacitor hole 860.

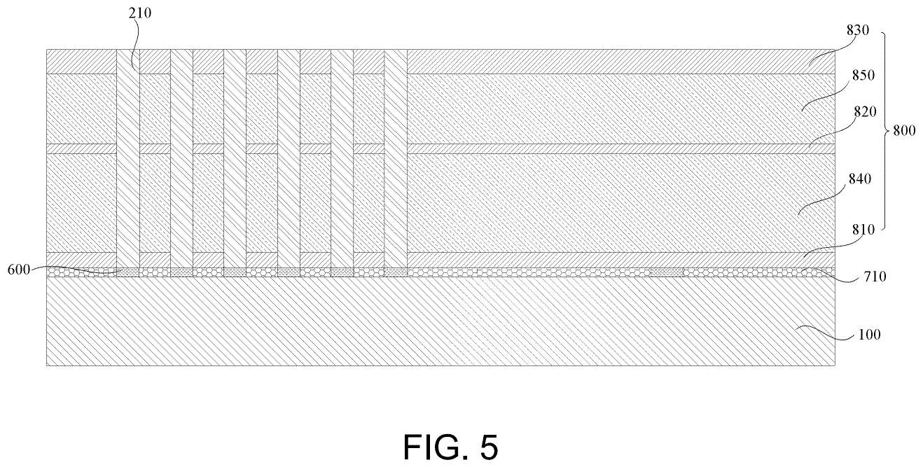

With reference to FIG. 5, a first electrode plate 210 is formed inside the capacitor hole 860 through a deposition process. The first electrode plate 210 fully fills the capacitor hole 860, and a top surface of the first electrode plate 210 is flush with the top surface of the support structure 800.

It should be noted that the aforementioned capacitor hole 860 divides the support structure 800 into multiple columnar structures. After the first electrode plate 210 is formed, it is necessary to remove a part of film layers of the support structure 800.

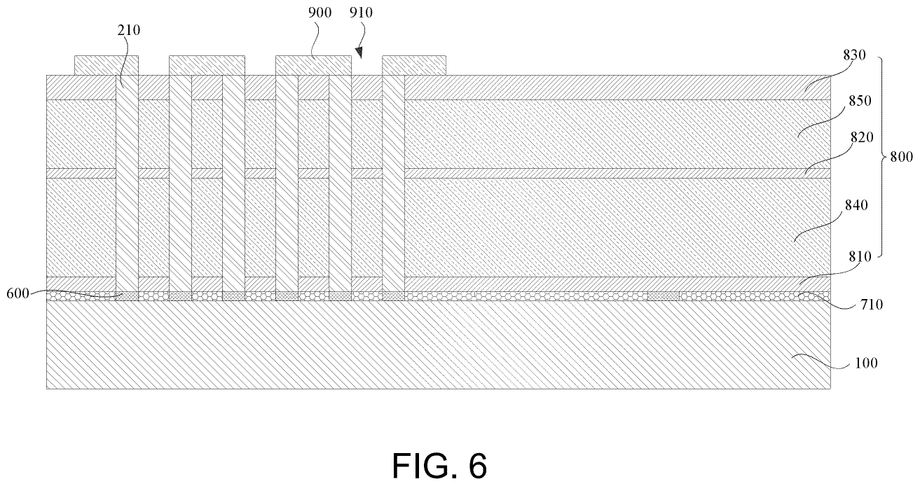

With reference to FIG. 6, a photoresist layer 900 is formed on the support structure 800, and then the photoresist layer 900 is patterned to form a mask opening 910 within the photoresist layer 900, a columnar structure being exposed through the mask opening 910. The number of mask openings 910 may be adjusted according to the structure of the semiconductor device.

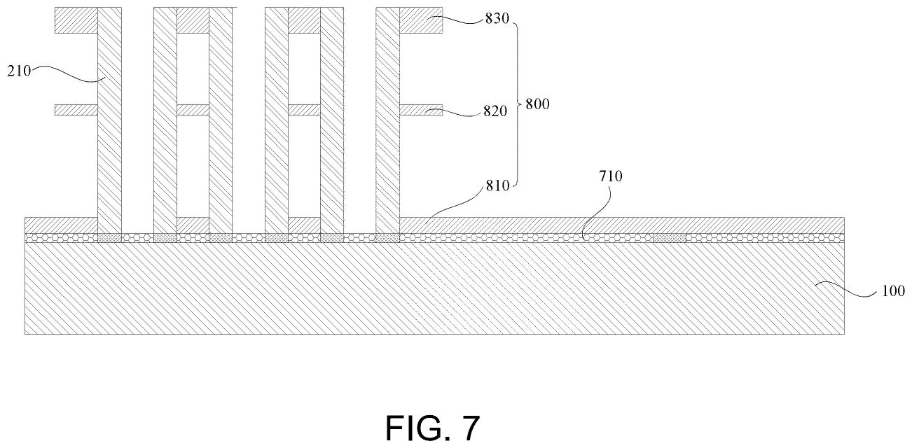

With reference to FIG. 7, the columnar structure exposed inside the mask opening 910 is removed through a wet etching process. Then, the photoresist layer 900, as well as the first sacrificial layer 840 and the second sacrificial layer 850 are continued to be removed through an etching process.

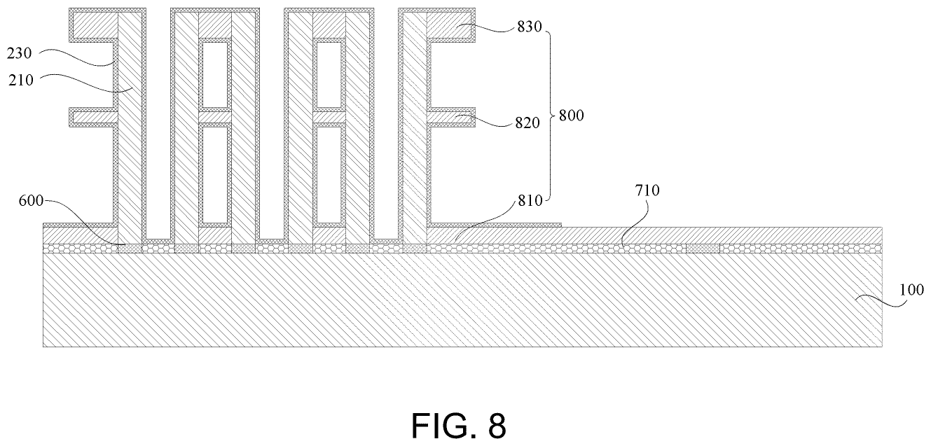

With reference to FIG. 8, a capacitor dielectric layer 230 is formed, which covers an exposed surface of the first electrode plate 210, a surface of the support structure 800, and a top surface of the capacitive contact structure 600.

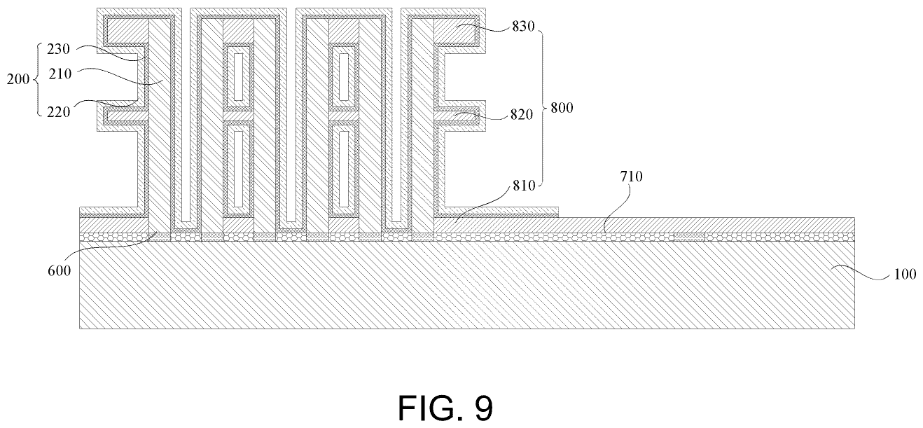

In one example, referring to FIG. 9, a second electrode plate 220 is formed on the capacitor dielectric layer 230 through a deposition process, and the second electrode plate 220 is a single film layer.

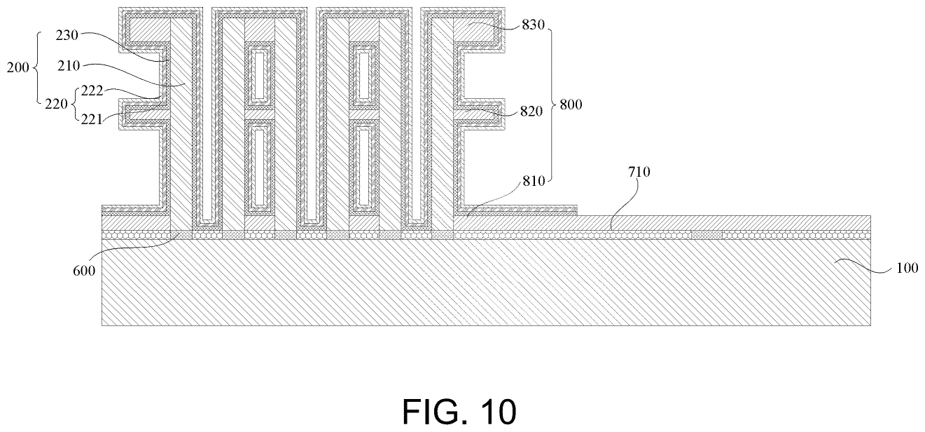

In another example, referring to FIG. 10, a barrier layer 221 and a conductive layer 222 that are stacked are formed on the capacitor dielectric layer 230 through a deposition process, where the barrier layer 221 and the conductive layer 222 constitute the second electrode plate 220. The barrier layer 221 is made of a material including titanium nitride, and the conductive layer 222 is made of a material including polycrystalline silicon.

The second electrode plate 220, along with the first electrode plate 210 located within one of the capacitor holes and the capacitor dielectric layer 230, forms a capacitor 200. In this way, first electrode plates 210 of multiple capacitors 200 are relatively independent, and each first electrode plate 210 is connected to a source or a drain of the transistor through a capacitive contact structure 600. And the multiple capacitors 200 are connected through the second electrode plate 220, facilitating electrical contact between the capacitors 200 and the semiconductor conductive layer 300.

Adopting a unified deposition process to form the second electrode plate 220 greatly simplifies the manufacturing process, reduces production steps and costs compared to the process of separately producing the second electrode plate 220 for each capacitor. Meanwhile, due to the continuity of the second electrode plate 220, defects and variations that may be introduced due to separate fabrication are reduced, thereby improving the yield and reliability of the semiconductor device.

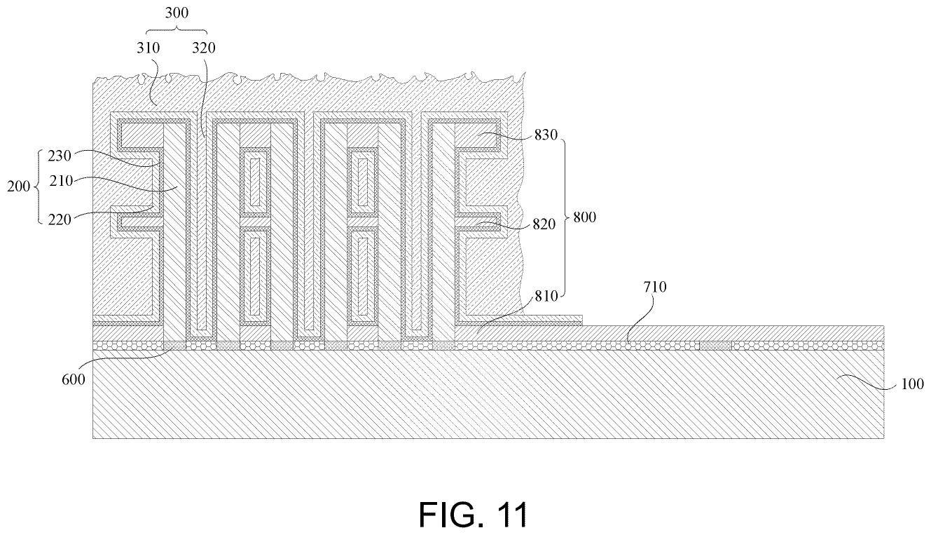

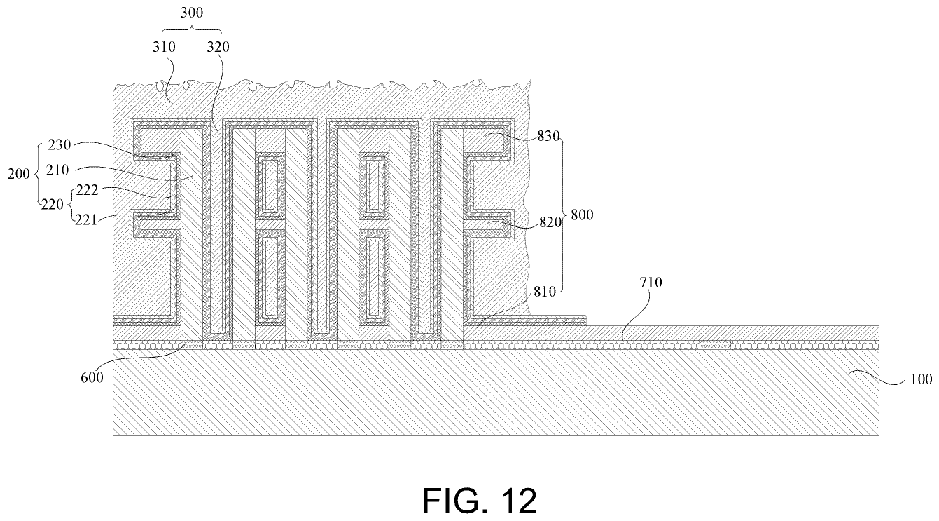

With reference to FIG. 11 and FIG. 12, a semiconductor conductive layer 300 is formed, which is disposed on the second electrode plate 220 and fully fills a region enclosed by the second electrode plate 220, where a top surface of the semiconductor conductive layer 300 is higher than a top surface of the second electrode plate 220. The part of the semiconductor conductive layer 300 filled in the region enclosed by the second electrode plate 220 forms the second portion 320, and the part of the semiconductor conductive layer 300 located above the support structure forms the first portion 310. The first portion 310 of the semiconductor conductive layer 300 covers the capacitor structure and directly contacts the capacitor structure.

It should be noted that the semiconductor conductive layer 300 with an uneven top surface is obtained through the deposition process, that is, the semiconductor conductive layer 300 has an uneven surface profile.

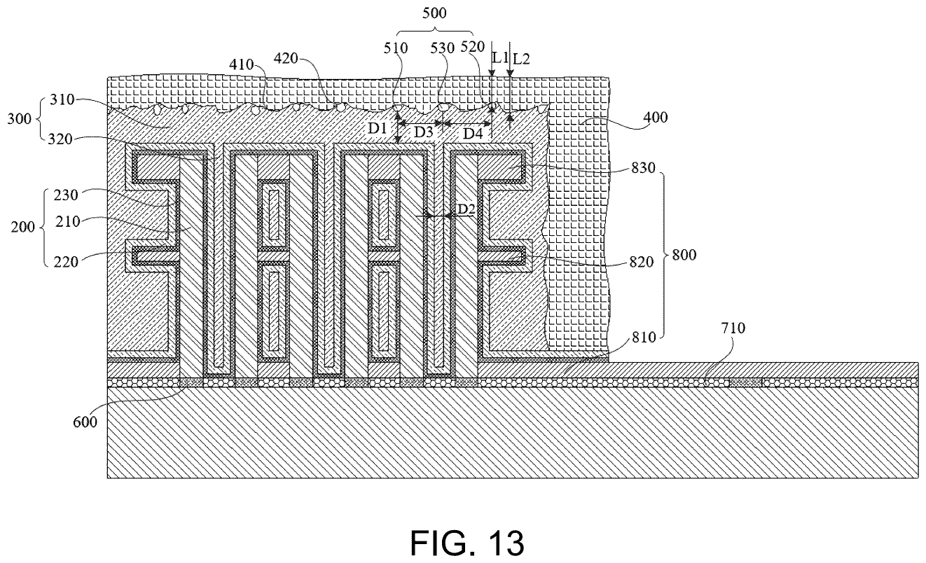

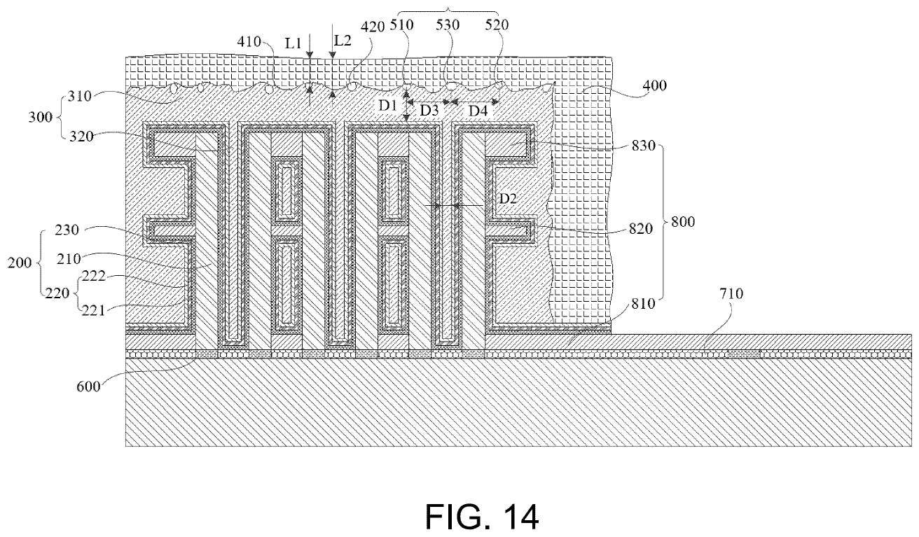

With reference to FIG. 13 and FIG. 14, a cover layer 400 is formed through a deposition process, which is located on the first portion 310 and in direct contact with the first portion 310; where a surface of the cover layer 400 facing the semiconductor conductive layer 300 has an undulating surface profile, and the surface profile has peaks 410 and valleys 420, the first portion 310 being extended into the valleys 420.

By adjusting a process parameter of the semiconductor conductive layer 300 and the cover layer 400, the semiconductor device includes multiple voids 500, at least one void is located within the first portion 310 in the valley 420. In this way, the use of multiple voids 500 may block the stress generated during the contraction or expansion process of the semiconductor conductive layer 300 and/or the cover layer 400, avoiding stress concentration at the interface between the semiconductor conductive layer 300 and the cover layer 400, thereby avoiding delamination between the semiconductor conductive layer 300 and the cover layer 400, and improving the performance of the semiconductor device.

With reference to FIG. 1, FIG. 15, and FIG. 16, an insulating layer 720 is formed through a deposition process, which covers the cover layer 400. It should be understood that the semiconductor device typically includes an array region and a peripheral circuit region, where the array region is used to form memory cells including transistors and capacitor structures. The peripheral circuit region is disposed on one side of the array region and connected to the array region.

The insulating layer 720 not only covers the cover layer 400, but also covers the first support layer 810 exposed on the peripheral circuit region.

A conductive plug 730 is formed, which is disposed within the insulating layer 720. The conductive plug 730 extends in a direction perpendicular to the substrate 100, and an end of the conductive plug 730 near the substrate 100 may be freely disposed according to a material of the cover layer 400, where the conductive plug 730 is located on the array region. For example, with reference to FIG. 15 and FIG. 16, when the cover layer 400 is made of a conductive material, for the conductive plug 730 located on the array region, an end of the conductive plug 730 near the substrate 100 is disposed inside the cover layer 400 or inside the semiconductor conductive layer 300. For another example, referring to FIG. 1, when the cover layer 400 is made of an insulating material, for the conductive plug 730 located on the array region, an end of the conductive plug 730 near the substrate 100 is disposed inside the semiconductor conductive layer 300.

An embodiment of the present application further provides a semiconductor apparatus, including a package and the semiconductor device described in any of the above embodiments.

The package encapsulates the semiconductor device, or in other words, the package is wrapped around the semiconductor device to protect it. On one hand, it prevents external moisture from entering the semiconductor device and affecting its normal use; on the other hand, it makes the encapsulated semiconductor device easier to transport and install.

In this embodiment, a top surface of the package is slightly higher than a top surface of the semiconductor device, which can prevent damage to the semiconductor device in a subsequent chemical mechanical polishing process and ensure the performance of the semiconductor device. The package is made of resin, but is not limited to resin.

Considering that the semiconductor apparatus in this embodiment includes the semiconductor device in any of the above embodiments, the semiconductor apparatus in this embodiment has the beneficial effects of the semiconductor device in the above embodiments, and details will not be further described in this embodiment.

The embodiments or implementations herein are described in a progressive manner, with each embodiment emphasizing its differences from other embodiments. A cross reference can be made to the same and similar parts between the embodiments.

It should be noted that the terms “one embodiment”, “embodiments”, “exemplary embodiments”, “some embodiments”, etc. mentioned herein indicate that the described embodiment may include a specific feature, structure, or characteristic, but not necessarily every embodiment includes such specific feature, structure, or characteristic. Furthermore, such phrases may not necessarily refer to the same embodiment. Furthermore, when describing a specific feature, structure, or characteristic in conjunction with an embodiment, implementing such feature, structure, or characteristic in conjunction with other embodiments that are explicitly or implicitly described is within the knowledge of the persons of ordinary skill in the art.

Finally, it should be noted that the above embodiments are only used to illustrate the technical solution of the present application, and not to limit it. Although the present application has been described in detail with reference to the aforementioned embodiments, the persons of ordinary skill in the art should understand that they can still modify the technical solutions described in the aforementioned embodiments, or equivalently replace some or all of the technical features; and these modifications or replacement do not deviate from the essence of the corresponding technical solutions from the scope of the technical solutions of the various embodiments of the present application.

What is claimed is:

1. A semiconductor device, comprising:
a substrate;
a capacitor structure disposed on the substrate, wherein the capacitor structure comprises a plurality of capacitors;
a semiconductor conductive layer comprising a first portion and a second portion, wherein the first portion covers the capacitor structure and directly contacts the capacitor structure, and the second portion is filled between adjacent capacitors;
a cover layer located on the first portion and in direct contact with the first portion, wherein a surface of the cover layer facing the semiconductor conductive layer has an undulating surface profile, and the surface profile has peaks and valleys, the first portion being extended into the valleys; and
a plurality of voids, wherein at least one void is located within the first portion in the valley.

2. The semiconductor device according to claim 1, wherein a bottom of the at least one void facing the substrate is located between an adjacent peak and a surface of the cover layer away from the substrate.

3. The semiconductor device according to claim 1, wherein there is a minimum distance D1 between the at least one void and a top surface of the capacitor structure away from the substrate,
there is a distance D2 between adjacent capacitors in the capacitor structure, and
the distance D1 is greater than the distance D2.

4. The semiconductor device according to claim 1, wherein the plurality of voids are disposed within the first portion at intervals.

5. The semiconductor device according to claim 1, wherein the plurality of voids comprise a first void, a second void, and a third void, the third void being located within the first portion in the valley,
in a first direction, the first void is located at one side of the third void, and the second void is located at the other side of the third void,
there is a first spacing D3 between the first void and the third void, and there is a second spacing D4 between the second void and the third void, wherein the first spacing D3 is less than or equal to the second spacing D4.

6. The semiconductor device according to claim 1, wherein widths of the void gradually decrease along a direction of the cover layer pointing towards the semiconductor conductive layer.

7. The semiconductor device according to claim 6, wherein when a section perpendicular to the substrate is taken as a longitudinal section, the void has a longitudinal section shape which is conical or trapezoidal.

8. The semiconductor device according to claim 6, wherein when a section perpendicular to the substrate is taken as a longitudinal section, the void has a longitudinal section shape which is semi-circular or arc-shaped.

9. The semiconductor device according to claim 1, wherein the semiconductor conductive layer is made of a material comprising silicon germanium.

10. The semiconductor device according to claim 1, wherein the cover layer is made of an insulating material,
the insulating material is selected from at least one of: high-density plasma (HDP) oxide, tetraethyl orthosilicate (TEOS), undoped silica glass (USG), phosphosilicate glass (PSG), borosilicate glass (BSG), borophosphosilicate glass (BPSG), fluorinated silicate glass (FSG), spin-on glass (SOG), tetraorthosilicate zirconium (TOSZ), silicon nitride or silicon nitride oxide.

11. The semiconductor device according to claim 1, wherein the cover layer is made of a conductive material,
the conductive material is selected from at least one of: tungsten, titanium nitride, or tungsten nitride.

12. The semiconductor device according to claim 1, wherein the capacitor comprises a first electrode plate, a second electrode plate, and a capacitor dielectric layer located between the first electrode plate and the second electrode plate,
the semiconductor conductive layer is disposed on the second electrode plate.

13. A semiconductor apparatus, comprising a package and a semiconductor device, and the package encapsulates the semiconductor device, wherein the semiconductor device comprises:
a substrate;
a capacitor structure disposed on the substrate, wherein the capacitor structure comprises a plurality of capacitors;
a semiconductor conductive layer comprising a first portion and a second portion, wherein the first portion covers the capacitor structure and directly contacts the capacitor structure, and the second portion is filled between adjacent capacitors;
a cover layer located on the first portion and in direct contact with the first portion, wherein a surface of the cover layer facing the semiconductor conductive layer has an undulating surface profile, and the surface profile has peaks and valleys, the first portion being extended into the valleys; and
a plurality of voids, wherein at least one void is located within the first portion in the valley.

14. The semiconductor apparatus according to claim 13, wherein a bottom of the at least one void facing the substrate is located between an adjacent peak and a surface of the cover layer away from the substrate.

15. The semiconductor apparatus according to claim 13, wherein there is a minimum distance D1 between the at least one void and a top surface of the capacitor structure away from the substrate,
there is a distance D2 between adjacent capacitors in the capacitor structure, and
the distance D1 is greater than the distance D2.

16. The semiconductor apparatus according to claim 13, wherein the plurality of voids are disposed within the first portion at intervals.

17. The semiconductor apparatus according to claim 13, wherein the plurality of voids comprise a first void, a second void, and a third void, the third void being located within the first portion in the valley,
in a first direction, the first void is located at one side of the third void, and the second void is located at the other side of the third void,
there is a first spacing D3 between the first void and the third void, and there is a second spacing D4 between the second void and the third void, wherein the first spacing D3 is less than or equal to the second spacing D4.

18. The semiconductor apparatus according to claim 13, wherein widths of the void gradually decrease along a direction of the cover layer pointing towards the semiconductor conductive layer.

19. The semiconductor apparatus according to claim 18, wherein when a section perpendicular to the substrate is taken as a longitudinal section, the void has a longitudinal section shape which is at least one of: conical, trapezoidal, semi-circular or arc-shaped.

20. The semiconductor apparatus according to claim 13, wherein the cover layer is made of an insulating material or a conductive material.
